(19) United States
(12) Patent Application Publication
(10) Pub. No.: US 2019/0165129 A1
(43) Pub. Date: May 30, 2019

(54) FABRICATING TRANSISTORS WITH A DIELECTRIC FORMED ON A SIDEWALL OF A GATE MATERIAL AND A GATE OXIDE BEFORE FORMING SILICIDE

(71) Applicant: TEXAS INSTRUMENTS INCORPORATED, Dallas, TX (US)

(72) Inventors: Alexei SADOVNIKOV, Sunnyvale, CA (US); Natalia LAVROVSKAYA, Sunnyvale, CA (US)

(21) Appl. No.: 15/824,665

(22) Filed: Nov. 28, 2017

(51) Int. Cl. H01L 29/66; H01L 29/739

(52) U.S. Cl. CPC H01L 29/66325; H01L 29/6625; H01L 29/7393

(57) ABSTRACT

A method to fabricate a transistor includes implanting dopants in a semiconductor to form a collector region having majority carriers of a first type, implanting dopants in the collector region to form a base region, forming a gate oxide on the base region, forming a gate material on the gate oxide, forming the gate material and the gate oxide to leave uncovered an emitter area of the base region, forming an emitter region, and forming a dielectric to cover a first area of the emitter region and a first sidewall of the gate material and the gate oxide while leaving uncovered a second area of the emitter region. Metal is deposited over the dielectric and the second area of the emitter region, and the semiconductor is annealed to form silicide in the second area of the emitter region.

### BACKGROUND

Bipolar junction transistors are often used in many high performance analog applications to amplify or buffer analog signals, such as audio amplifiers. In such applications, it is desirable for bipolar junction transistors to exhibit relatively low 1/f noise and popcorn noise, and yet have a relatively high transistor beta.

### SUMMARY

In accordance with at least one embodiment, a method to fabricate a transistor comprises: implanting dopants in a semiconductor to form a collector region having majority carriers of a first type; implanting dopants in the collector region to form a base region having majority carriers of a second type; forming a gate oxide on the base region; forming a gate material on the gate oxide; forming the gate material and the gate oxide to leave uncovered an emitter area of the base region; implanting dopants in the emitter area to form an emitter region having majority carriers of the first type; forming a dielectric to cover a first area of the emitter region and a first sidewall of the gate material and the gate oxide, and to leave uncovered a second area of the emitter region; depositing a metal over the dielectric and the second area of the emitter region; and annealing the semiconductor to form silicide in the second area of the emitter region, wherein forming the dielectric to cover the first area of the emitter region and the first sidewall of the gate material and the gate oxide is performed before annealing the semiconductor to form silicide.

In accordance with at least one embodiment, the dielectric comprises a silicide block.

In accordance with at least one embodiment, the method further comprises: forming the gate material and the gate oxide to leave uncovered a base contact drain area of the base region; and implanting dopants in the base contact area of the base region to form a base contact region having majority carriers of the second type.

In accordance with at least one embodiment, the method further comprises: forming the dielectric to cover a first area of the base contact region and a second sidewall of the gate material and the gate oxide, and to leave uncovered a second area of the base contact region; depositing the metal over the second area of the base contact region; and when annealing the semiconductor, forming silicide in the second area of the base contact region, wherein forming the dielectric to cover the first area of the base contact region and the second sidewall of the gate material and the gate oxide is performed before annealing the semiconductor to form silicide.

In accordance with at least one embodiment, the dielectric comprises silicon dioxide.

In accordance with at least one embodiment, the gate material comprises polysilicon.

In accordance with at least one embodiment, the metal comprises tungsten.

In accordance with at least one embodiment, the method further comprises removing the metal that has not formed the silicide.

In accordance with at least one embodiment, the majority carriers of the first type are holes and the majority carriers of the second type are electrons.

In accordance with at least one embodiment, the method further comprises: implanting dopants in the collector region to form a well having majority carriers of the first type; implanting dopants in the well to form a collector contact region having majority carriers of the first type; depositing the metal over the collector contact region; and when annealing the semiconductor, forming silicide in the collector contact region.

In accordance with at least one embodiment, a second method to fabricate a transistor comprises: implanting dopants in a semiconductor to form a collector region having majority carriers of a first type; implanting dopants in the collector region to form a base region having majority carriers of a second type; growing a gate oxide on the semiconductor; depositing a gate material on the gate oxide; etching the gate material and the gate oxide to expose an emitter area of the base region surrounded by a first sidewall of the gate material and the gate oxide, and to expose a base contact area of the base region, the base contact area surrounding a second sidewall of the gate material and the gate oxide; implanting dopants in the emitter area to form an emitter region having majority carriers of the first type; implanting dopants in the base contact area of the base region to form a base contact region having majority carriers of the second type; depositing a dielectric over the semiconductor; etching the dielectric to cover the first sidewall of the gate material and the gate oxide, the dielectric after etching exposing a portion of the semiconductor; depositing metal over the dielectric and the exposed portion of the semiconductor; and annealing the semiconductor to form silicide in the exposed portion of the semiconductor.

In accordance with at least one embodiment, the second method to fabricate a transistor further comprises etching the dielectric to cover the second sidewall of the gate material and the gate oxide.

In accordance with at least one embodiment, in the second method to fabricate a transistor, the dielectric comprises silicon dioxide, and the second method further comprises removing the metal from the dielectric.

In accordance with at least one embodiment, in the second method to fabricate a transistor, the majority carriers of the first type are holes and the majority carriers of the second type are electrons.

In accordance with at least one embodiment, a transistor comprises: a collector region having majority carriers of a first type; a base region having majority carriers of a second type; an emitter region having majority carriers of the first type, the emitter region having a first area and a second area; silicide, wherein the silicide is formed in the second area of the emitter region; a gate oxide over the base region; and a gate material on the gate oxide, the gate material and the gate oxide having a first sidewall, wherein the silicide formed in the second area of the emitter region is separated from the first sidewall by a distance of at least 0.1 microns.

In accordance with at least one embodiment, the first area of the emitter region surrounds the second area of the emitter region, and the first sidewall surrounds the first area of the emitter region.

In accordance with at least one embodiment, the transistor further comprises a base contact region in the base region having majority carriers of the second type, wherein the base contact region has a first area and a second area, and wherein the silicide is formed in the second area of the base contact region.

In accordance with at least one embodiment, wherein the gate material and the gate oxide have a second sidewall, the second area of the base contact region surrounds the first area of the base contact region, and the first area of the base contact region surrounds the second sidewall.

In accordance with at least one embodiment, further comprising a silicide block formed on the first sidewall and on the first area of the emitter region.

In accordance with at least one embodiment, in the transistor, the majority carriers of the first type are holes and the majority carriers of the second type are electrons.

### BRIEF DESCRIPTION OF THE DRAWINGS

For a detailed description of various examples, reference will now be made to the accompanying drawings in which:

FIG. 1 shows an illustrative transistor in accordance with various examples;

FIG. 2 shows an illustrative transistor in accordance with various examples;

FIG. 3 shows an illustrative transistor in accordance with various examples;

FIG. 4 shows an illustrative transistor in accordance with various examples;

FIG. 5 shows an illustrative transistor in accordance with various examples; and

FIG. 6 shows an illustrative transistor fabrication process in accordance with various examples.

### DETAILED DESCRIPTION

In many high performance analog applications, a bipolar junction transistor (BJT) is often used to amplify, buffer, or condition an analog signal. In such applications, it is desirable for a transistor to have a relatively high beta, with relatively low 1/f noise and popcorn noise. In current fabrication process technology, it can be difficult to achieve both of these design objectives. A silicide block separating the emitter contact from the base contact in a transistor can be used to maintain a relatively high beta, but this design does not mitigate the noise. To mitigate the noise, a gate oxide, protected by a polysilicon gate, can be disposed between the emitter contact and the base contact, but in current fabrication process technology the polysilicon gate defines the emitter contact area and the base contact area, so that silicide formation on these areas may lead to a relatively low beta. It is desirable for a fabrication process and transistor design to maintain a relatively high beta with relatively low 1/f noise and popcorn noise.

In accordance with the disclosed embodiments, a transistor comprises a gate material on a gate oxide, disposed between an emitter region and a base contact region, where a dielectric is formed on a first sidewall of the gate material and the gate oxide before forming silicide. The dielectric formed on the first sidewall serves as a silicide block, preventing silicide from forming on the first sidewall, so that the silicide does not form on the entire area of the emitter region and is at a distance from the first sidewall. In some embodiments, the silicide formed on the emitter region is separated from the first sidewall by a distance of 0.1 microns to 1 microns. As discussed below, the silicide block on the first sidewall helps reduce 1/f noise and popcorn noise while maintaining a relatively high transistor beta. In accordance with the disclosed embodiments, the dielectric is formed on a second sidewall of the gate material and the gate oxide before forming silicide.

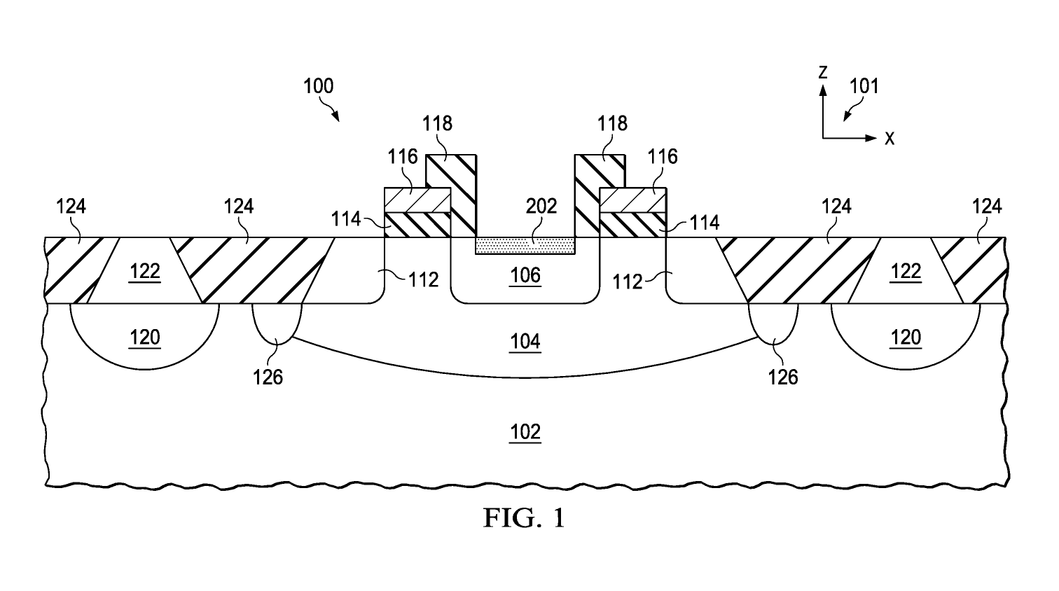

FIG. 1 shows an illustrative transistor 100 according to an embodiment. The illustrative transistor 100 is a bipolar junction transistor (BJT), and includes a collector region 102, a base region 104, and an emitter region 106. In some embodiments, the illustrative transistor 100 is a PNP transistor, where the collector region 102 and the emitter region 106 are P-type semiconductors, and the base region 104 is an N-type semiconductor. For a PNP transistor, the collector region 102 and the emitter region 106 can be fabricated by implanting acceptor dopants into a silicon semiconductor, and the base region 104 can be fabricated by implanting donor dopants into a silicon semiconductor.

FIG. 1 presents a cross-sectional slice of the illustrative transistor 100, and is not drawn to scale. FIG. 1 does not show various vias and metal layers that are fabricated in a back-end-of-line (BEOL) process to connect the illustrative transistor 100 to other devices (not shown) to form a circuit.

In some embodiments, the illustrative transistor 100 is an NPN transistor, where the collector region 102 and the emitter region 106 are N-type semiconductors, and the base region 104 is a P-type semiconductor. More generally, the collector region 102 and the emitter region 106 may be described as having majority carriers of a first type, and the base region 104 may be described as having majority carriers of a second type. For some embodiments, holes can be the first type of majority carriers and electrons can be the second type of majority carriers.

In describing the embodiments, without loss of generality a PNP transistor is illustrated and described, but the description of the embodiments is applicable to NPN transistors by considering that there are majority carriers of the first type and majority carriers of the second type, where for some embodiments electrons and holes are majority carriers of the first and second types, respectively, and for other embodiments holes and electrons are majority carriers of the first and second types, respectively.

FIG. 1 does not show the semiconductor substrate that the collector region 102 is formed in, nor does FIG. 1 show the semiconductor substrate as part of a wafer in which other devices may be integrated with the illustrative transistor 100. The collector region 102 may be fabricated within a well formed in the semiconductor substrate, and there may be shallow trench isolation (STI) regions to isolate the illustrative transistor 100 from other devices (not shown). The semiconductor material upon which the illustrative transistor 100 is fabricated may be obtained from crystalline silicon grown from a seed, or the semiconductor material may also include epitaxial layers grown upon a semiconductor substrate.

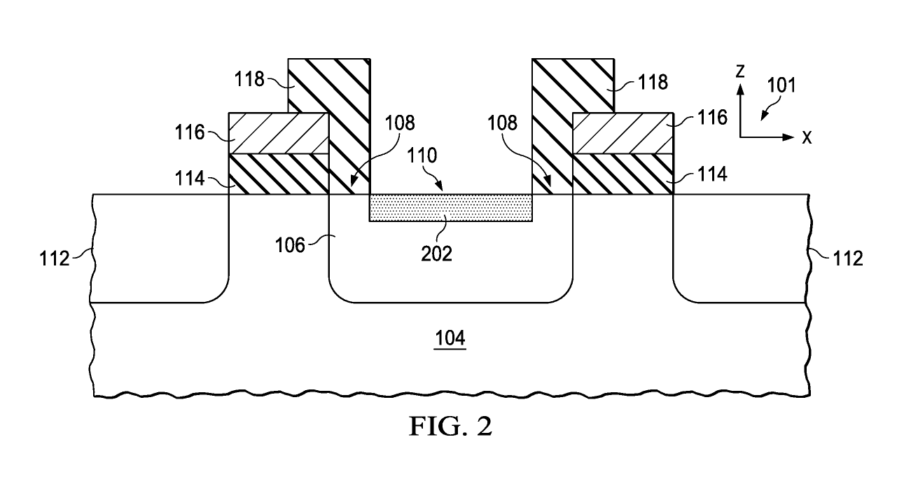

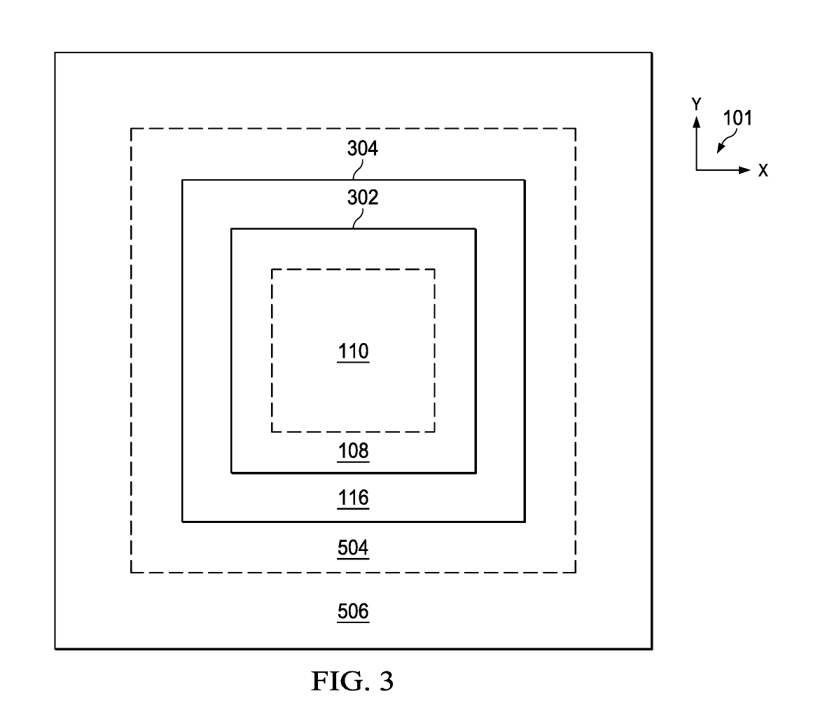

FIG. 2 shows the illustrative transistor 100 according to an embodiment, where several of the components in FIG. 1 are shown in more detail. FIG. 3 shows the illustrative transistor 100 according to an embodiment, where several of the components in FIG. 1 are shown in more detail, but with respect to a different orientation of view.

A coordinate system 101 shown in FIG. 1, FIG. 2, and FIG. 3, shows the relationship among the orientations of view depicted in these figures. In FIG. 1, the coordinate system 101 has its x-axis and z-axis in the page of the drawing, where the y-axis (not shown) points into the page of the drawing. In this orientation, the x-y plane of the coordinate system 101 is parallel to the surface of the semiconductor upon which the illustrative transistor 100 is fabricated.

In FIG. 2, the coordinate system 101 has the same orientation as shown in FIG. 1. In FIG. 3, the coordinate system 101 has its x-axis and y-axis lying in the page of the drawing, where the z-axis (not shown) points out of the page of the drawing. The x-y plane of the coordinate system 101 as shown in FIG. 3 is still parallel to the surface of the semiconductor upon which the illustrative transistor 100 is fabricated, but the orientation of view depicted in FIG. 3 may be described as looking down upon the illustrative transistor 100. As for FIG. 1, FIG. 2 and FIG. 3 do not show all components of the illustrative transistor 100 that are fabricated for an operational circuit, and these figures are not drawn to scale.

Referring to FIG. 2, the emitter region 106 has a first area 108 and a second area 110. FIG. 2 does not depict the diffusion of the emitter region 106 that would occur during fabrication. For example, in practice some of the emitter region 106 would diffuse underneath the gate oxide 114. In practice, the union of the first area 108 and the second area 110 is somewhat less than the entire area of the emitter region 106, although FIG. 2 does not show this.

In some embodiments, the first area 108 surrounds the second area 110. FIG. 3 shows the first area 108 surrounding the second area 110. FIG. 3 shows the first area 108 and the second area 110 of the emitter region 106 as having rectangular boundaries, but this depiction is a simplification.

Referring to FIG. 2, silicide 202 is formed in the second area 110 of the emitter region 106. Depositing a metal onto the second area 110 of the emitter region 106, and then annealing forms the silicide 202. The metal may comprise tungsten. The silicide 202 provides electrical connection of the emitter region 106 to other circuit components (not shown).

Referring to FIG. 1, a base contact region 112 is formed in the base region 104 to provide ohmic contact to the base region 104. The base contact region 112 may be formed by source-drain implantation. For the example in which the illustrative transistor 100 is a PNP transistor, the base contact region 112 is an N-type semiconductor. For example, donor dopants may be implanted into the base region 104 to form the base contact region 112.

A gate oxide 114 is formed over the base region 104, illustrated in FIG. 1 and FIG. 2. For some embodiments, the gate oxide 114 may comprise silicon dioxide (SiO₂), and is a high-quality oxide thermally grown on the semiconductor upon which the illustrative transistor 100 is fabricated.

Formed over the gate oxide 114 is a gate material 116, illustrated in FIG. 1 and FIG. 2. The gate material 116 may comprise polysilicon, and protects the gate oxide 114 during subsequent processing steps that could damage the gate oxide 114 if the gate material 116 were not present. For some embodiments, the combination of the gate oxide 114 and the gate material 116 surround the emitter region 106. This is illustrated in FIG. 3, showing the gate material 116 surrounding the first area 108 of the emitter region 106. (FIG. 3 does not show the gate oxide 114 because it lies underneath the gate material 116.)

The combination of the gate oxide 114 and the gate material 116 may be described as being disposed between the emitter region 106 and the base contact region 112. Isolating the emitter region 106 from the base contact region 112 with a high quality oxide provided by the gate oxide 114 helps with the 1/f noise and popcorn noise of the illustrative transistor 100 during operation in a circuit, such as an analog amplifier.

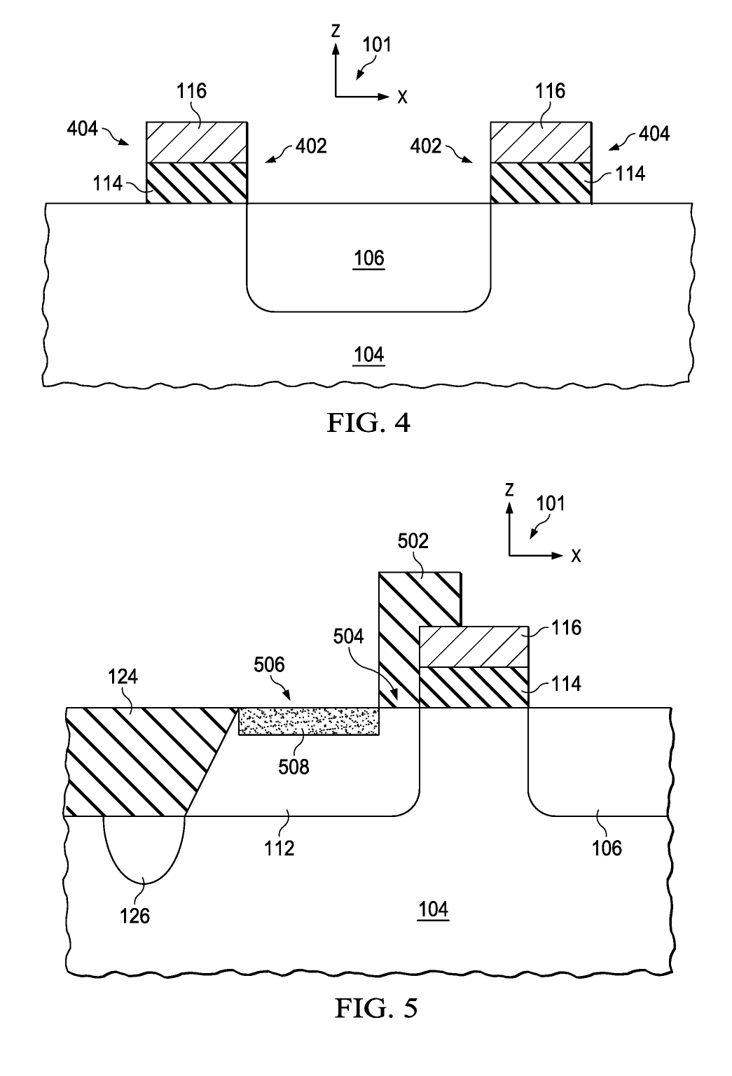

FIG. 4 shows the illustrative transistor 100 according to an embodiment, where several of the components in FIG. 1 are shown in more detail. The gate material 116 and the gate oxide 114 may be described as having a first sidewall 402 and a second sidewall 404. The gate material 116 and the gate oxide 114 can serve as a hard mask when implanting dopants to form the emitter region 106 and the base contact region 112, so that the first sidewall 402 may be viewed as defining a boundary of the emitter region 106 and the second sidewall 404 may be viewed as defining a boundary of the base contact region 112.

Because of diffusion, the previous statement regarding the boundaries of the emitter region 106 and the base region 112 is only approximate, and there is no precise definition to these boundaries, nor are these boundaries exactly aligned with the sidewalls. Nevertheless, for purposes of illustrating the embodiments, FIG. 3 shows a boundary 302 of the emitter region 106 that ideally is aligned with the first sidewall 402, and a boundary 304 of the base contact region 112 that ideally is aligned with the second sidewall 404. The first sidewall 402 may be described as surrounding the first area 108 of the emitter region 106. The boundary 304 of the base contact region 112 may be described as surrounding the second sidewall 404.

Referring to FIG. 1 (or FIG. 2), a silicide block 118 is formed on the first sidewall 402. Referring to FIG. 2, the silicide block 118 covers the first area 108 of the emitter region 106. The silicide block 118 leaves uncovered (or exposed) the second area 110 of the emitter region 106. The silicide block 118 is deposited on the first sidewall 402 before depositing metal to form the silicide 202. When annealing the semiconductor with metal to form the silicide 202, the silicide block 118 prevents silicide from forming on the first sidewall 402. The silicide block 118 is disposed between the silicide 202 and the first sidewall 402.

The silicide block 118 comprises a dielectric, where metal deposited on the silicide block 118 is prevented from forming a silicide with the silicon directly beneath the silicide block 118. For some embodiments, the silicide block 118 comprises silicon dioxide, and is formed by depositing silicon dioxide onto the surface of the semiconductor upon which the illustrative transistor 100 is fabricated. For some embodiments, the silicide block 118 is deposited over the entire surface of the semiconductor upon which the illustrative transistor 100 is fabricated, and is selectively etched away to cover the first sidewall 402 (and other components if desired). For example, anisotropic etching may be performed so that some silicon dioxide remains on the first sidewall 402.

The silicide block 118 restricts formation of the silicide 202 to the second area 110 rather than to the entire area of the emitter region 106 if the silicide block 118 were not present. With the silicide block 118 present before forming the silicide 202, formation of the silicide 202 is kept at a distance from the first sidewall 402, where for some embodiments this distance may be from 0.1 microns to 1 microns. Referring to FIG. 1, it may be seen that for a PNP transistor, electrons injected laterally from the base region 104 into the emitter region 106 experience more acceptors on their way to the silicide 202 than if there was silicide over the entire area of the emitter region 106. Acceptors present a potential barrier to electrons, and consequently the silicide block 118 helps mitigate lateral injection of base current to the emitter region 106, thereby increasing transistor beta.

For a PNP transistor, some of the electrons injected vertically from the base region 104 into the emitter region 106 may encounter the silicide block 118, and are expected to be reflected back into the base region 104, thereby further reducing base current and contributing to an increase in transistor beta.

Referring to FIG. 1, dopants are implanted in the collector region 102 to form a first well 120, and dopants are implanted in the first well 120 to form a collector contact region 122. The collector contact region 122 may be formed by source-drain implantation. An STI region 124 is formed between the collector contact region 122 and the base contact region 112 to provide electrical isolation. For a PNP transistor, the first well 120 and the collector contact region 122 are p-type semiconductors. A second well 126 may be formed in the collector region 102 between the base contact region 112 and the collector contact region 122 to provide electrical isolation.

FIG. 5 shows the illustrative transistor 100 according to an embodiment, where several of the components in FIG. 1 are shown in more detail. A silicide block 502 is formed on the second sidewall 404. The silicide block 502 may be formed when the silicide block 118 is formed. For example, silicon dioxide may be deposited over the semiconductor upon which the illustrative transistor 100 is fabricated, and the deposited silicon dioxide is etched back anisotropically to leave silicon dioxide on the sidewalls.

The silicide block 502 covers a first area 504 of the base contact region 112, leaving uncovered (exposed) a second area 506 of the base contact region 112. Depositing metal followed by annealing forms a silicide 508 in the second area 506 of the base contact region 112. (FIG. 1 does not show the silicide 508.) Forming the silicide 508 may be concurrent with forming the silicide 202. The silicide block 502 is deposited on the second sidewall 404 before forming the silicide 508, so that the silicide block 502 prevents silicide from forming in the first area 504 of the base contact region 112, and prevents silicide from forming on the second sidewall 404. The silicide block 502 is disposed between the silicide 508 and the second sidewall 404.

Referring to FIG. 3, the second area 506 of the base contact region 112 surrounds the first area 504 of the base contact region 112. In practice, due to diffusion the union of the first area 504 and the second area 506 is somewhat less than the entire area of the base contact region 112, although for purposes of describing the embodiments the union of the first area 504 and the second area 506 may be viewed as representing the entire area of the base contact region 112. Accordingly, FIG. 3 shows that the base contact region 112 surrounds the gate material 116. Ideally, the boundary 304 of FIG. 3 is aligned with the second sidewall 404, so that FIG. 3 shows that the first area 504 of the base contact region 112 surrounds the second sidewall 404.

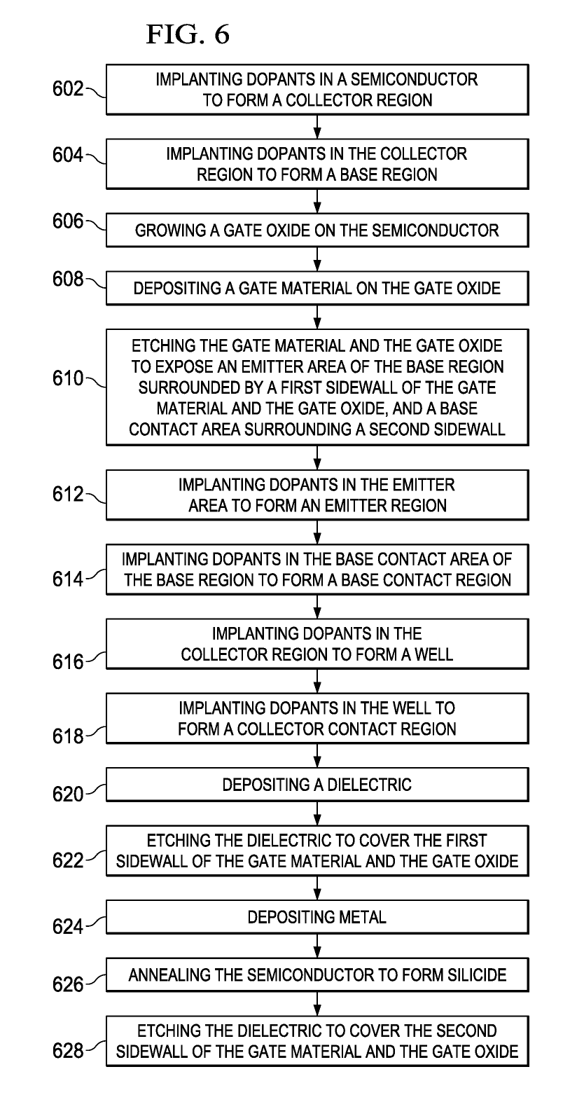

FIG. 6 shows an illustrative process for fabricating the illustrative transistor 100 according to an embodiment. In step 602 dopants are implanted in a semiconductor to form a collector region having majority carriers of a first type, and in step 604 dopants are implanted in the collector region to form a base region having majority carriers of a second type. In step 606, a gate oxide is grown on the semiconductor, and in step 608 a gate material is deposited on the gate oxide.

In step 610, the gate material and the gate oxide are etched to expose an emitter area of the base region, and to expose a base contact area in the base region. The etching of the gate material and the gate oxide forms a first sidewall and a second sidewall. For some embodiments, the first sidewall of the gate material and the gate oxide surround the emitter area. (Other embodiments could be directed to fabricating lateral transistors.) For some embodiments, the base contact area surrounds the second sidewall of the gate material and the gate oxide.

The gate material and the gate oxide after etching can serve as a hard mask for defining the emitter area, as well as defining other areas for implanting dopants. In step 612, dopants are implanted in the emitter area to form an emitter region having majority carriers of the first type. In step 614, dopants are implanted in the base contact area to form a base contact region having majority carriers of the second type.

Steps 616 and 618 form the collector region of the transistor, where in step 616 dopants are implanted in the collector region to form a well having majority carriers of the first type, and in step 618 dopants are implanted in the well to form a collector contact drain region having majority carriers of the first type to make contact with the collector region.

Before implanting dopants, a photoresist film is deposited and exposed with radiation by one or more lithography masks, followed by baking and etching of the photoresist film to define a pattern on the semiconductor for the dopant implantation. However, such steps are not included in FIG. 6.

In step 620, a dielectric is deposited over the semiconductor. For example, silicon dioxide may be deposited by CVD. This dielectric serves as a silicide block. In step 622, the dielectric is etched to cover the first sidewall of the gate material and the gate oxide. In step 624, metal is deposited over the surface of the semiconductor and the dielectric, followed by annealing in step 626 so that the metal in contact with silicon forms silicide. In step 628, for some embodiments, the dielectric deposited in step 624 may be etched so as to cover the second sidewall of the gate material and the gate oxide.

The listing of steps in FIG. 6 does not necessarily imply a corresponding ordering of the steps when fabricating a transistor according to an embodiment. However, the steps 620 and 622 to deposit and etch dielectric to form a silicide block on the first sidewall is performed before the steps of 624 and 626 to form silicide in the emitter region. Similarly, the steps 620 and 628 to deposit and etch dielectric to form a silicide block on the second sidewall is performed before the steps of 624 and 626 to form silicide in the base contact region.

The above discussion is meant to be illustrative of the principles and various embodiments of the present disclosure. Numerous variations and modifications will become apparent to those skilled in the art once the above disclosure is fully appreciated. It is intended that the following claims be interpreted to embrace all such variations and modifications.

1. A method fabricating a transistor, the method comprising:
a first implant process comprising implanting a first dopant having a first conductivity type in a semiconductor to form a collector region having majority carriers of a first type;
a second implant process comprising implanting a second dopant having a second different conductivity type into the collector region to form a base region having majority carriers of a second type;
forming a gate oxide on the base region;
forming a gate material on the gate oxide;
patterning the gate material and the gate oxide thereby exposing an emitter area of the base region;
implanting dopants in the emitter area to form an emitter region having majority carriers of the first type;
forming a dielectric that covers a top surface of the gate material, a first area of the emitter region and a first sidewall of the gate material and the gate oxide, and leaves uncovered a second area of the emitter region;
depositing a metal over the dielectric and the second area of the emitter region; and
annealing the semiconductor to form silicide in the second area of the emitter region, wherein forming the dielectric to cover the first area of the emitter region and the first sidewall of the gate material and the gate oxide is formed before annealing the semiconductor to form silicide.

2. The method of claim 1, wherein the dielectric comprises a silicide block.

3. The method of claim 1, further comprising:
forming the gate material and the gate oxide, leaving uncovered a base contact drain area of the base region; and
implanting dopants in the base contact area of the base region to form a base contact region having majority carriers of the second type.

4. The method of claim 3, further comprising:
forming the dielectric thereby covering a first area of the base contact region and a second sidewall of the gate material and the gate oxide, and leaving uncovered a second area of the base contact region;
depositing the metal over the second area of the base contact region; and
when annealing the semiconductor, forming silicide in the second area of the base contact region, wherein forming the dielectric to cover the first area of the base contact region and the second sidewall of the gate material and the gate oxide is performed before annealing the semiconductor to form silicide.

5. The method of claim 1, wherein the dielectric comprises silicon dioxide.

6. The method of claim 1, wherein the gate material comprises polysilicon.

7. The method of claim 1, wherein the metal comprises tungsten.

8. (canceled)

9. The method of claim 1, wherein the majority carriers of the first type are holes and the majority carriers of the second type are electrons.

10. The method of claim 1, further comprising:
implanting dopants in the collector region to form a well having majority carriers of the first type;
implanting dopants in the well to form a collector contact region having majority carriers of the first type;
depositing the metal over the collector contact region; and
when annealing the semiconductor, forming silicide in the collector contact region.

11. A method of fabricating a transistor, the method comprising:
forming a collector region having majority carriers of a first type in a semiconductor substrate;
forming a base region having majority carriers of a second type;
forming a gate oxide on the semiconductor;
forming a gate material on the gate oxide;
etching the gate material and the gate oxide, exposing an emitter area of the base region surrounded by a first sidewall of the gate material and the gate oxide, and exposing a base contact area of the base region, the base contact area surrounding a second sidewall of the gate material and the gate oxide;
implanting a first dopant in the emitter area thereby forming an emitter region having majority carriers of the first type;
implanting a second dopant in the base contact area of the base region thereby forming a base contact region having majority carriers of the second type;
depositing a dielectric over the semiconductor;
patterning the dielectric, thereby forming a first dielectric portion covering a top surface of the gate material, the first sidewall of the gate material and the gate oxide, and exposing a portion of the semiconductor;
depositing metal over the dielectric portion and the exposed portion of the semiconductor; and
annealing the semiconductor to form silicide on or over the exposed portion of the semiconductor.

12. The method of claim 11, wherein patterning the dielectric comprises forming a second dielectric portion that covers the top surface, the second sidewall of the gate material and the gate oxide.

13. The method of claim 11, wherein the dielectric comprises silicon dioxide, the method further comprising removing the metal from the dielectric after the annealing.

14. The method of claim 11, wherein the majority carriers of the first type are holes and the majority carriers of the second type are electrons.

15-20: (canceled)

21. The method of claim 2, wherein the silicide block comprises silicon nitride.

22. The method of claim 11, wherein the dielectric comprises silicon and nitrogen.

23. A method of forming an integrated circuit, comprising:
implanting a dopant having a first conductivity type into a semiconductor substrate thereby forming a first doped region having the first conductivity type;
implanting a dopant having a second different conductivity type into the first doped region, thereby forming a second doped region within the first doped region and having the second conductivity type;
forming a polysilicon structure over the first doped region, the polysilicon structure having a top surface and first and second side surfaces;
forming a dielectric structure that covers at least one of the first or second side surfaces and the top surface; and
forming a metal silicide adjacent the dielectric structure.

24. The method of claim 23, wherein forming the silicide includes said dielectric structure blocking the silicide adjacent the first or second side surfaces.

25. The method of claim 23, wherein the dielectric structure covers both the first and second sidewalls.

26. The method of claim 23, wherein the dielectric structure forms a closed ring located at a perimeter of the second doped region.

27. The method of claim 23, wherein the polysilicon structure masks the implanting of the dopant having the second conductivity type.

28. The method of claim 23, wherein the first doped region comprises a base region located in a collector region, and the second doped region conductivity type is p-type and the second conductivity type is n-type.

29. The method of claim 23, wherein the first conductivity type is p-type and the second conductivity type is n-type.

30. The method of claim 23, wherein the dielectric structure comprises silicon nitride.
